(19) United States
(12) Patent Application Publication
(10) Pub. No.: US 2008/0174335 A1
(43) Pub. Date: Jul. 24, 2008

(54) TEST APPARATUS FOR DETERMINING PERFORMANCE DEGRADATION

(76) Inventor: Yuichi Maekawa, Sagamihara-shi (JP)

Correspondence Address: Frank Pincelli;Patent Legal Staff, Eastman Kodak Company, 343 State Street, Rochester, NY, 14650-2201, US

(21) Appl. No.: 11/852,343

(22) Filed: Sep. 10, 2007

(30) Foreign Application Priority Data
Sep. 20, 2006 (JP) 2006-255063

(51) Int. Cl. G01R 31/26

(52) U.S. Cl. 324/769

(57) ABSTRACT

Provided is a testing apparatus that accurately tests changes in threshold value of a transistor. The output of an operational amplifier is connected to the gate of a transistor to be tested, and the source of the transistor to be tested is negatively fed back to the negative input terminal of the operational amplifier. By applying desired voltage from a DAC to the positive input terminal of the operational amplifier, the operational amplifier operates so as to maintain a current flowing in the resistor at a constant value, thereby performing a test where the current flowing in the transistor to be tested is maintained at a constant value.

### CROSS-REFERENCE TO RELATED APPLICATION

This application claims priority of Japanese Patent Application No. 2006-255063 filed Sep. 20, 2006 which is incorporated herein by reference in its entirety.

### FIELD OF THE INVENTION

The present invention relates to a testing apparatus that tests characteristic changes due to the use of transistors.

### BACKGROUND OF THE INVENTION

Conventionally, a liquid crystal display (LCD), an organic EL display (OLED display), or the like has employed an active matrix where elements for display control are provided for each pixel.

For example, there exists an AMOLED display where amorphous silicon thin film transistors (a-Si:H TFT) are used as elements for driving the OLED element of each pixel. In the AMOLED, it is necessary to prevent abnormal display due to current changes, which are caused by the changes in drain current—gate voltage characteristics of a transistor with time. Therefore, the AMOLED display is preferably provided with a compensation function that causes the drain current to flow to the OLED element in accordance with the initial drain current—gate voltage characteristics, even when the characteristics have changed.

In a display having such a compensation function, an a-Si:H TFT for driving the OLED element maintains the drain current flowing to the OLED element at a constant value by changing gate voltage while maintaining drain-source voltage at substantially a constant value. Therefore, grasping a-Si:H TFT characteristics under the same stress as encountered in actual operation is essential for achieving a display which is resistant to burn-in and which has a long life. However, the above-described a-Si:H TFT characteristics under the same stress have conventionally been grasped by a method using software that measures the drain current and calculates voltage to be applied to a gate on a personal computer (P-26:TFT Degradation Due to Two-Interface Charge Injection, Takatoshi Tsujimura, Journal Eurodisplay 1996, pgs. 299-301).

The conventional method has a long response time from application of stress to a point where desired drain current is reached, and accurately determining the initial value of gate voltage is difficult. The initial value of gate voltage must be known in order to calculate a change in drain current when the gate voltage is changed, in order to maintain the drain current at a constant value. Since estimation of life varies significantly by the dispersion of the initial value, accurately grasping the characteristics is difficult.

### SUMMARY OF THE INVENTION

The present invention provides a testing apparatus that tests performance degradation of a transistor to be tested, including: a stress application circuit that includes an operational amplifier, where an output terminal is connected to the gate of the transistor to be tested, a negative input terminal is connected to the source of the transistor to be tested, and a positive input terminal is connected to the output of a gate power source; a resistor that is connected between the negative input terminal and a negative power source, and causes flow, in the resistor, of the drain current flowing in the transistor to be tested, and a drain power source that supplies predetermined drain voltage to the drain of the transistor to be tested; and measuring means that is connected to each of the drain, source, and gate terminals of the transistor to be tested and measures the electrical characteristics of the transistor to be tested, wherein the apparatus applies stress where drain current flowing in the transistor to be tested is maintained at a constant value and detects the characteristic changes of the transistor to be tested in response to the stress by supplying, to the positive input terminal of the operational amplifier, a gate command, obtained when target drain current is flowing in the resistor, by causing a predetermined drain current to flow to the transistor to be tested, and detecting a measurement value of the measuring means.

Further, switches are preferably provided between the respective terminals of the stress application circuit and the transistor to be tested, as well as between the respective terminals of the measuring means and the transistor to be tested, whereby switching can be effected between stress application to the transistor to be tested and electrical characteristic measurement of the transistor to be tested.

Further, the gate power source preferably includes a digital-analog converter, and the drain current flowing in the transistor to be tested can be set on the basis of digital data.

Further, the drain power source preferably includes the digital-analog converter, and the drain current flowing in the transistor to be tested can be set on the basis of digital data.

Further, the apparatus preferably has monitoring means for monitoring the voltage of each terminal of the transistor to be tested when the drain current is flowing in the transistor to be tested by the stress application circuit.

Further, the present invention provides a testing apparatus that has: a stress application circuit that includes an operational amplifier, where an output terminal is connected to the gate of the transistor to be tested, a negative input terminal is connected to the source of the transistor to be tested, and a positive input terminal is connected to the output of a gate power source; a resistor that is connected between the negative input terminal and a negative power source, and causes flow, in the resistor, of the drain current flowing in the transistor to be tested, and a drain power source that supplies predetermined drain voltage to the drain of the transistor to be tested; and measuring means that is connected to each of the drain, source, and gate terminals of the transistor to be tested and measures the electrical characteristics of the transistor to be tested, in which the apparatus applies stress where drain current flowing in the transistor to be tested is maintained at a constant value and detects the characteristic changes of the transistor to be tested in response to the stress, by supplying, to the positive input terminal of the operational amplifier, a gate command, obtained when target drain current flows in the resistor, by causing a predetermined drain current to flow the transistor to be tested, and detecting a measurement value of the measuring means, wherein the apparatus is provided with monitoring means for monitoring the voltage of each terminal of the transistor to be tested when the stress application circuit causes flow of the drain current in the transistor to be tested, switches are provided between the respective terminals of the stress application circuit and the transistor to be tested, as well as between the respective terminals of the measuring means and the transistor to be tested, and computer software controls the switches, the gate power source, the drain power source, and the monitoring means.

### BRIEF DESCRIPTION OF THE DRAWINGS

FIG. 1 is a view showing the constitution of a testing apparatus of an embodiment of the present invention;

FIG. 2 is a view showing an example of changes in a threshold voltage with time;

FIG. 3 is a view showing another example constitution of the testing apparatus of the invention; and

FIG. 4 is a view showing testing of a P-channel transistor.

### DESCRIPTION OF PREFERRED EMBODIMENTS

Hereinafter, the embodiment will be described with reference to the drawings.

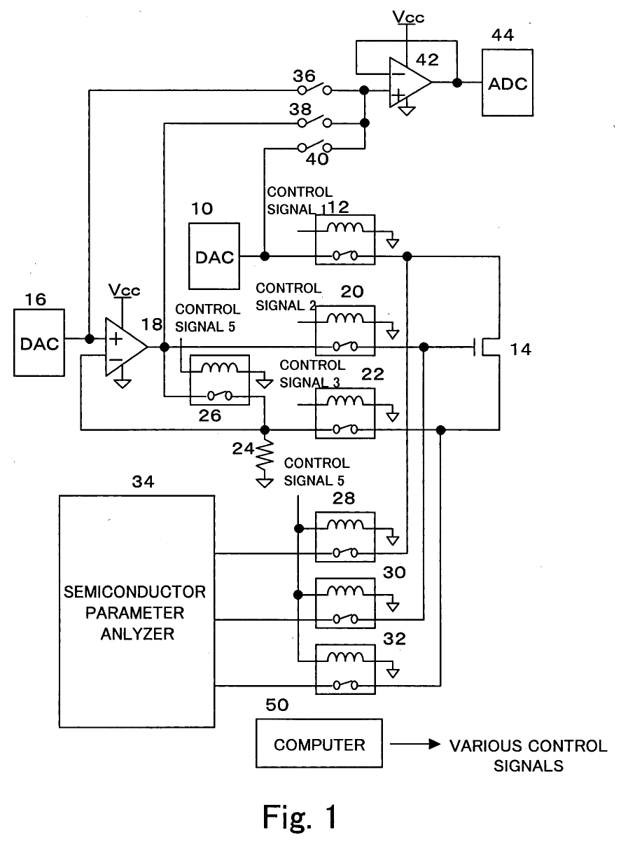

FIG. 1 shows the constitution of the testing apparatus according to the embodiment. The output terminal of a digital to analog converter (DAC) 10 that converts digital data into analog voltage is connected to the drain of an N-channel transistor to be tested 14, via a relay 12 that is turned ON/OFF by a control signal 1. Further, the output terminal of a DAC 16 is connected to the positive input terminal of an operational amplifier 18. The output terminal of the operational amplifier 18 is connected to the gate of the transistor to be tested 14 via a relay 20 that is turned ON/OFF by a control signal 2. The source of the transistor to be tested 14 is connected to the negative input terminal of the operational amplifier 18 via a relay 22 that is turned ON/OFF by a control signal 3, and the negative input terminal of the operational amplifier 18 is connected to the ground via a resistor 24.

The output terminal of the operational amplifier 18 is connected to the negative input terminal of the operational amplifier 18 via a relay 26 that is turned ON/OFF by a control signal 4.

Further, the drain, the gate, and the source of the transistor to be tested 14 are connected to a semiconductor parameter analyzer 34 via a relay 28, a relay 30, and a relay 32, respectively. It should be noted that the relays (28, 30, 32) are controlled to turn ON/OFF by a control signal 5.

Moreover, the output of the DAC 10, the output of the DAC 16, and the output of the operational amplifier 18 are connected to an ADC 44 that performs analog-digital conversion, via switches (36, 38, 40), respectively, and a buffer amplifier 42.

In such an apparatus, when the relays (12, 20, 22) are turned ON, the relays (26, 28, 30, 32) are turned OFF, and the switches (36, 38, 40) are turned OFF, the output of the DAC 12 is supplied to the drain of the transistor to be tested 14, the output of the DAC 16 is supplied to the positive input terminal of the operational amplifier 18, and the output of the operational amplifier 18 is supplied to the gate of the transistor to be tested 14. Meanwhile, the source of the transistor to be tested 14 is fed back to the negative input terminal of the operational amplifier 18, and connected to the ground via the resistor 24. Therefore, the output of the operational amplifier 18 is adjusted such that voltage output from the DAC 16 appears at the source of the transistor to be tested 14, and thus, current flowing in the resistor 24; that is, the drain current of the transistor to be tested 14, is adjusted by the output voltage of the DAC 16.

Then, when the threshold voltage of the transistor to be tested 14 is changed and the drain current is about to change, the output of an operational amplifier changes to make the drain current a constant value, because the negative feedback is applied to the operational amplifier 18. Therefore, in this circuit the gate voltage of the transistor to be tested 14 is automatically controlled to make the drain current assume a constant value at all times.

Further, by turning the relays (12, 20, 22) OFF and turning the relays (28, 30, 32) ON, stress application to the transistor to be tested 14 is stopped, and each terminal of the transistor to be tested 14 can be connected to the semiconductor parameter analyzer 34, whereby the characteristics of the transistor to be tested 14 can be detected in this state.

Moreover, by selecting any of the switches (36, 38, 40), the output of the DAC 10, the output of the DAC 16, and the output of the operational amplifier 18 can be input to the ADC 44, and thus the voltage input to the output of the ADC 44 can be obtained as a digital value.

Further, by turning the relays (12, 20, 22, 28, 30, 32) OFF, turning the relay 26 ON, and turning the switch 38 ON, the output of the operational amplifier 18 is applied directly to the resistor 24, and voltage drop in the resistor 24 at the time when the output voltage of the DAC 16 is applied to the resistor 24 can be checked by the output of the ADC 44. In other words, since the resistance value of the resistor 24 is known, the amount of current flowing in the resistor 24 can be checked and the output error of the operational amplifier 18 can be also detected.

Moreover, the apparatus is provided with a computer 50, and the output of the ADC 44 can be stored and the output of the relays, switches, and the DACs can be controlled by executing the software of the computer.

In this embodiment, the drain current of the transistor to be tested 14 is determined by the operational amplifier 18. Particularly, because the source voltage of the transistor to be tested 14 is determined by the negative feedback to the operational amplifier 18, it is easy to set the gate voltage of the transistor to be tested 14 to a voltage (initial value) corresponding to desired drain current.

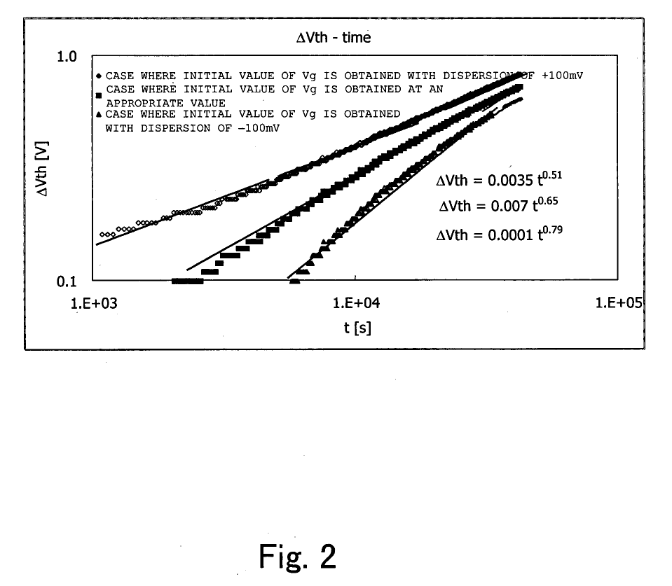

FIG. 2 shows the changes ΔVth with time of a threshold value in a stress test where the drain voltage and the drain current are set to constant values. Herein, ΔVth=Vg(t)−initial Vg holds, where Vg(t) is gate voltage Vg at time (t), and the initial Vg is gate voltage Vg at the starting time of the stress test. Further, an a-Si:H TFT serving as the transistor to be tested 14 is operated in a saturation region.

In FIG. 2, the topmost characteristics are ΔVth-time characteristics when the initial value of gate voltage is dispersed by +100 mV, where 100 mV was added to measure initial value. The middle characteristics are time characteristics of ΔVth when the initial value of gate voltage was properly obtained with good accuracy, and are measured values. The bottom characteristics are time characteristics of ΔVth when the initial value of gate voltage was dispersed by −100 mV, where 100 mV was subtracted from the measured initial values.

When power approximation is performed by reference to the results plotted in FIG. 2 to calculate time when ΔVth=20V is obtained, the above-described three characteristics respectively have 2.0×107[s], 7.1×106[s], and 4.9×106[s], and dispersion of 0.7 to 2.7 times occurs. As described, it is impossible to accurately grasp the characteristics if the initial value of the gate voltage shifts. Therefore, accurately obtaining the initial value of Vg is extremely important.

In this embodiment, the actions of measuring the drain current and controlling the voltage applied to the gate are realized by a single operational amplifier 18. This can accelerate response time from the application of stress to a point where desired drain current is reached, and the initial value of the gate voltage can be determined with good accuracy by the stress test where the drain voltage and the drain current of an amorphous silicon thin film transistor (a-Si:H TFT) are maintained at constant values. Then, an appropriate stress application test can be performed by determining the initial value with good accuracy.

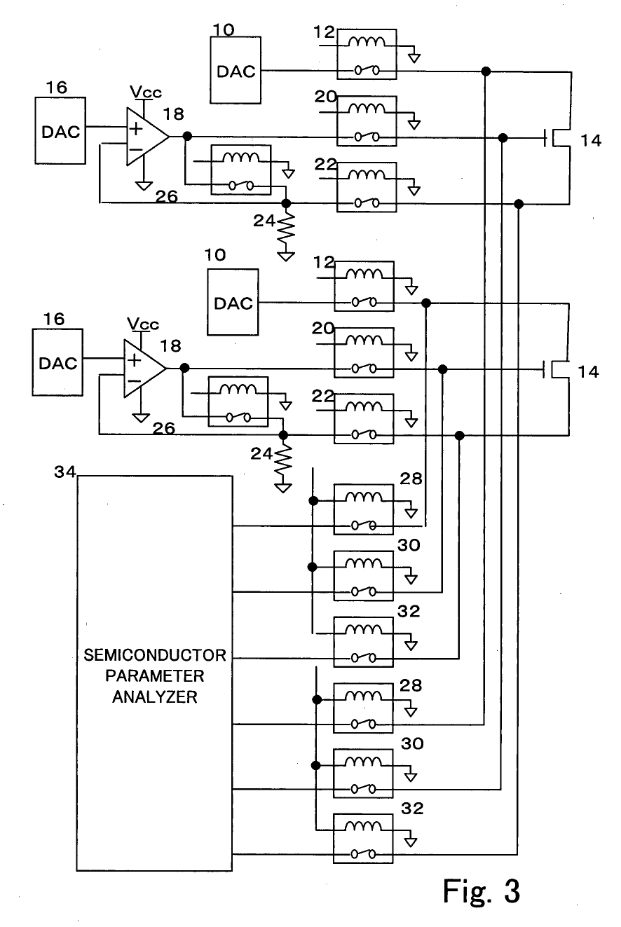

By employment of the testing apparatus shown in FIG. 3, the degradation characteristics of the drain characteristics of a plurality of the transistors to be tested 14 (a-Si:H TFT) can be evaluated simultaneously by connecting the above-described test circuits (constant current circuits) in parallel. It should be noted that, although in FIG. 3 two circuits are connected in parallel, three or more circuits may be connected in parallel.

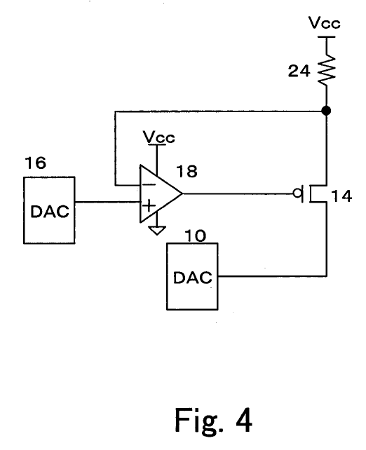

The transistor to be tested 14 may be either an N-channel type or a P-channel type. FIG. 4 shows the circuit using the P-channel transistor to be tested 14. In this case, the resistor 24 is arranged between the source of the transistor to be tested 14 and a positive power source.

Further, the transistor to be tested 14 is not limited to the amorphous silicon thin film transistor, but may be, for example, an organic transistor or the like.

Moreover, since this testing apparatus is capable of maintaining an electric field, which is applied to the channel section of the transistor to be tested 14, at a constant intensity regardless of characteristic fluctuation, it can be used to analyze the degradation mechanism of a TFT.

According to the present invention, the drain current of the transistor to be tested is controlled by the operational amplifier. Therefore, the operation of current value control is performed at high speed, and the initial value of the gate voltage of the transistor to be tested is set accurately, thereby enabling the stress application test of the transistor to be tested.

The invention has been described in detail with particular reference to certain preferred embodiments thereof, but it will be understood that variations and modifications can be effected within the spirit and scope of the invention.

### Parts List

2 control signal
3 control signal
4 control signal
5 control signal
10 digital to analog converter
12 relay
14 tested
16 DAC
18 operational amplifier
20 relay
22 relay
24 resistor
26 relay
28 relay
30 relay
32 relay
34 analyzer
36 switch
38 switch
40 switch
42 buffer amplifier
44 ADC
50 computer

1. A testing apparatus that tests performance degradation of a transistor to be tested, the apparatus comprising:
a stress application circuit that includes an operational amplifier, where an output terminal is connected to the gate of the transistor to be tested, a negative input terminal is connected to the source of the transistor to be tested, and a positive input terminal is connected to the output of a gate power source; a resistor that is connected between the negative input terminal and a negative power source and causes flow, in the resistor, of the drain current flowing in the transistor to be tested, and a drain power source that supplies predetermined drain voltage to the drain of the transistor to be tested; and
measuring means connected to each of the drain, source, and gate terminals of the transistor to be tested and measures the electrical characteristics of the transistor to be tested, wherein
the apparatus applies stress where the drain current flowing in the transistor to be tested is maintained at a constant value and detects the characteristic changes of the transistor to be tested in response to stress, by supplying to the positive input terminal of the operational amplifier a gate command, obtained when the target drain current is caused to flow in the resistor, by causing a predetermined drain current to flow to the transistor to be tested, and detecting a measurement value of the measuring means.

2. The testing apparatus according to claim 1, wherein:
switches are provided between the respective terminals of the stress application circuit and the transistor to be tested, as well as between the respective terminals of the measuring means and the transistor to be tested, and switching can be effected between stress application to the transistor to be tested and electrical characteristic measurement of the transistor to be tested.

3. The testing apparatus according to claim 1, wherein:
the gate power source includes a digital-analog converter, and is capable of using digital data to set the drain current flowing in the transistor to be tested.

4. The testing apparatus according to claim 1, wherein:
the drain power source includes the digital-analog converter, and is capable of using digital data to set the drain current flowing in the transistor to be tested.

5. The testing apparatus according to claim 1, further comprising:
monitoring means for monitoring the voltage of each terminal of the transistor to be tested when the drain current is caused to flow, by the stress application circuit, in the transistor to be tested.

6. A testing apparatus, comprising:
a stress application circuit that includes an operational amplifier, where an output terminal is connected to the gate of the transistor to be tested, a negative input terminal is connected to the source of the transistor to be tested, and a positive input terminal is connected to the output of a gate power source; a resistor that is connected between the negative input terminal and a negative power source and causes flow, into the resistor, of the drain current flowing in the transistor to be tested, and a drain power source that supplies predetermined drain voltage to the drain of the transistor to be tested; and
measuring means that is connected to each of the drain, source, and gate terminals of the transistor to be tested and measures the electrical characteristics of the transistor to be tested, wherein
the apparatus applies stress where the drain current flowing in the transistor to be tested is maintained at a constant value and detects the characteristic changes of the transistor to be tested in response to the stress, by supplying to the positive input terminal of the operational amplifier a gate command, obtained when target drain current flows in the resistor, by causing flow of predetermined drain current to the transistor to be tested, and detecting a measurement value of the measuring means,
the apparatus is provided with monitoring means for monitoring the voltage of each terminal of the transistor to be tested when the drain current is caused to flow in the transistor to be tested by the stress application circuit,
switches are provided between the respective terminals of the stress application circuit and the transistor to be tested as well as between the respective terminals of the measuring means and the transistor to be tested, and
computer software for controlling the switches, the gate power source, the drain power source, and the monitoring means.
